(19) United States
(12) Patent Application Publication
(10) Pub. No.: US 2016/0053403 A1
(43) Pub. Date: Feb. 25, 2016

(54) METHOD OF EPITAXIAL GROWTH OF A GERMANIUM FILM ON A SILICON SUBSTRATE

(71) Applicant: National Central University, Jhongli City (TW)

(72) Inventors: Jenq-Yang Chang, Taipei City (TW); Chien-Chieh Lee, Puzi City (TW); Teng-Hsiang Chang, Taoyuan City (TW); Chiao Chang, Taoyuan City (TW); Tomi T. Li, Longtan Township (TW); I-Chen Chen, Taoyuan City (TW); Mao-Jen Wu, Kaohsiung City (TW); Sheng-Hui Chen, Hsinchu City (TW)

(21) Appl. No.: 14/555,654

(22) Filed: Nov. 27, 2014

(30) Foreign Application Priority Data
Aug. 21, 2014 (TW) 103128851

(51) Int. Cl. C30B 25/10; C30B 29/08; C30B 30/00; H01L 21/02; C30B 25/18

(52) U.S. Cl. CPC C30B 25/10; H01L 21/02381; H01L 21/02532; H01L 21/02598; H01L 21/0262; C30B 25/186; C30B 25/18; C30B 30/00; C30B 29/08

(57) ABSTRACT

A method of epitaxial growth of a germanium film on a silicon substrate includes the steps of: providing a silicon substrate, placing the silicon substrate in a vacuum chamber, heating the silicon substrate to a temperature that is lower than 300° C., and forming a monocrystalline germanium film on the silicon substrate in the vacuum chamber, by employing an electron cyclotron resonance chemical vapor deposition (ECR-CVD) approach, wherein the step of forming a monocrystalline germanium film on the silicon substrate in the vacuum chamber further includes dissociating a reaction gas introduced into the vacuum chamber in utilization of a microwave source, such that the monocrystalline germanium film is deposited on the silicon substrate, and wherein the reaction gas includes at least germane (GeH₄) and hydrogen gas (H₂).

### FIELD OF THE INVENTION

The invention relates to a method for preparing a monocrystalline germanium film, and more particularly, to a method of epitaxial growth of germanium film on a silicon substrate by employing an electron cyclotron resonance chemical vapor deposition approach.

### BACKGROUND OF THE INVENTION

In the present industries, the crystalline silicon solar cell, regarded as a mainstream product in the market, is well-known by its most achievable photo-electric conversion efficiency of 24.7%. Further, once a much preferable efficiency in conversion of solar energy is desired, it is possible for a multi junction layout of solar cells to achieve a photo-electric conversion efficiency as high as 44.7%. However, in fact, the advancement of the multi-junction solar cell, which is principally composed of III-V compound semiconductor materials, fails to progress tremendously. It is because a germanium substrate or a gallium arsenide substrate employed in the multi-junction solar cell has a confined area, and is costly and suffer from a poor thermal conductivity, resulting in a disadvantageous popularity thereof.

Moreover, in order to substitute for the conventionally high-priced germanium substrate and improve the thermal conductivity, another solar cell technology involving epitaxially growth of germanium on a silicon substrate (hereinafter referred to as “Ge on Si”) has been developed gradually. However, in the present technology of epitaxially growing germanium on the silicon substrate, it is necessary to perform manufacturing processes mostly in a higher temperature (such as 600 to 800° C.). In addition, a higher-temperature annealing process (such as 900° C.) is usually accompanied. Unfortunately, the manufacturing processes at the higher temperatures will cause thermal stress defects resulted from the discrepancy in the thermal expansion coefficients of the silicon substrate and the germanium material, and result in a reduction in device yield rate. Besides, it will be uneasy to achieve the integration with the existing technology of silicon semiconductor manufacturing processes in such a high-temperature environment and rather complex manufacturing processes.

The primary spirits of this invention resides in providing a lower-temperature manufacturing processes suitable for allowing the epitaxial growth of germanium on a silicon substrate.

### SUMMARY OF THE INVENTION

Therefore, the invention provides a method of the epitaxial growth of germanium film on a silicon substrate, suitable for improving the device yield rate, attaining the cost down of the manufacturing processes, and advantaging an integration of the manufacturing processes.

In order to achieve the above and other advantages, according to an embodiment of the invention, a method of epitaxial growth of a germanium film on a silicon substrate is provided, that comprises the steps of providing a silicon substrate, placing the silicon substrate in a vacuum chamber, heating the silicon substrate to a temperature that is lower than 300° C., and forming a monocrystalline germanium film on the silicon substrate in the vacuum chamber, by employing an electron cyclotron resonance chemical vapor deposition approach, wherein the step of forming a monocrystalline germanium film on the silicon substrate in the vacuum chamber includes dissociating a reaction gas as introduced into the vacuum chamber in utilization of a microwave source, such that the monocrystalline germanium film is deposited on the silicon substrate, and wherein the reaction gas includes at least germane (GeH₄) and hydrogen gas (H₂).

In summary, the invention employs an electron cyclotron resonance chemical vapor deposition approach for effectively dissociating a reaction gas at a process temperature lower than 300° C., so as to enable the epitaxial growth of monocrystalline germanium film on silicon substrate and to prepare the monocrystalline germanium film with a surface roughness smaller than 3 nm. Here, it is worth mentioning that, according to the embodiment, throughout the epitaxial growth of monocrystalline germanium film according to the embodiment, it can be carried out at a process temperature lower than 300° C., and any annealing process is even needless. Thus, not only the thermal stress defects resulted from the distinct coefficients of thermal expansion of the silicon and germanium materials can be avoided as the manufacturing processes of Ge on Si are carried out at a low temperature according to the embodiment, but also the various restrictions on the components arisen in the conventional high-temperature process can be relieved. Consequently, it is advantageous for one to integrate the existing silicon-based semiconductor manufacturing processes with each other via the manufacturing processes of Ge on Si at a low temperature according to the embodiment.

### BRIEF DESCRIPTION OF THE DRAWINGS

The foregoing and other objects, features, and advantages of the invention will become more apparent and better understood by referring to the following embodiments taken in conjunction with the accompanying drawings, in which:

FIGS. 1A-1C are schematic diagrams depicting a method of epitaxial growth of a germanium film on a silicon substrate according to one embodiment of the invention;

FIG. 2 is an X-ray diffraction spectrum of a monocrystalline germanium film as prepared by manufacturing processes according to one embodiment, depicting crystallographic quality results thereof as measured by a X-ray diffractometer;

FIG. 3 is a graph depicting lattice constants vs. bandgaps of monocrystalline germanium and III-V materials; and

FIG. 4 is a sequential process flow chart depicting a method of epitaxial growth of a germanium film on a silicon substrate according to one embodiment of the invention.

### DETAILED DESCRIPTION OF PREFERRED EMBODIMENTS

Hereinafter, the objects, features and advantages of the invention will become more apparent from the detailed description set forth below, together with the drawings.

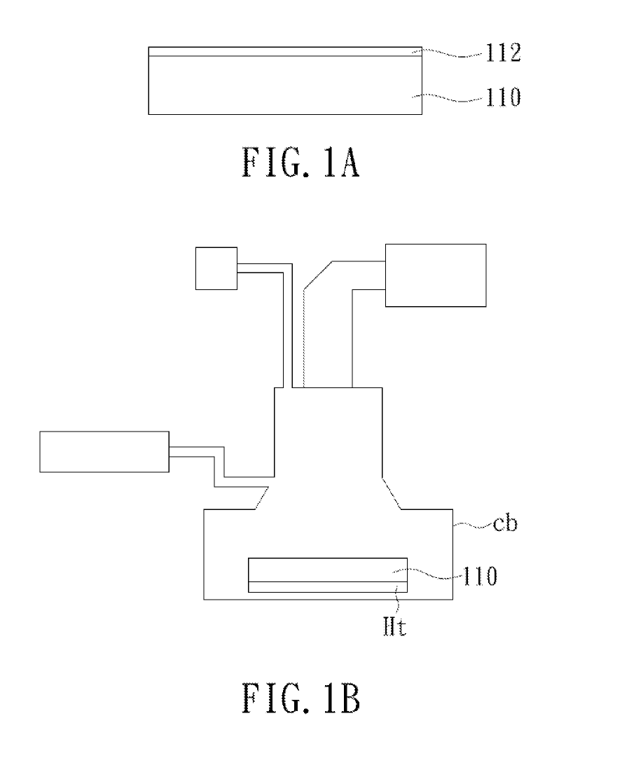

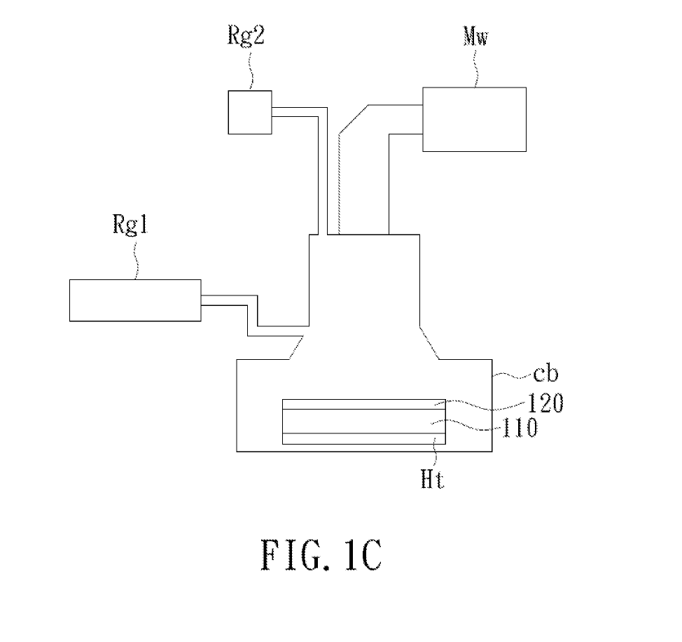

FIGS. 1A-1C are schematic diagrams depicting a method of epitaxial growth of a germanium film on a silicon substrate according to one embodiment of the invention. Referring to FIG. 1A, the method of epitaxial growth of a germanium film on a silicon (Ge on Si) substrate in accordance with an embodiment includes the steps set forth below. First, a silicon substrate 110 is provided. Preferably, the silicon substrate 110 has a crystallographic orientation such as the orientation of (100), or an orientation inclined by an angle of 6 degrees with respect to (100). Moreover, since a pre-existing oxidation layer 112 usually and potentially exists on the silicon substrate 110, it is preferable that the method of the embodiment further includes a step of eliminating or removing the pre-existing oxidation layer 112 on the silicon substrate 110 by employing a hydrofluoric acid solution prior to the deposition of the monocrystalline germanium film. The step of eliminating the pre-existing oxidation layer 112 by employing the hydrofluoric acid solution is exemplified by immersing the silicon substrate 110 in a hydrofluoric acid solution with a concentration of 1%-10% for about 5 seconds to 2 minutes, such that the pre-existing oxidation layer 112 existing on the silicon substrate 110 can be eliminated or removed.

Referring to FIGS. 1A and 1B simultaneously, after eliminating the pre-existing oxidation layer 112 on the silicon substrate 110, the silicon substrate 110 is placed in a vacuum chamber Cb. The vacuum chamber Cb is evacuated, and a heating plate Ht disposed in the vacuum chamber Cb is utilized for heating the silicon substrate 110 to a temperature T1, wherein the temperature T1 is lower than 300° C. In accordance with an embodiment, the temperature T1 falls in or is set at, for example, a range between 150° C. and 200° C. According to an embodiment of the invention, with the monocrystalline germanium film as prepared at a temperature T1 of 180° C., the subsequent processes and measurements thereof will be described below, but it should be deemed as an exemplification, instead of limitation. Moreover, it is worth mentioning that, after heating the silicon substrate 110 to the temperature T1, it is preferable, for example, to await until an achievement of thermal equilibrium for several minutes (such as, about 5-10 minutes) is obtained. Then, the deposition process of monocrystalline germanium film is subsequently performed as soon as the silicon substrate 110 maintains at the temperature T1 in thermal equilibrium.

Next, referring to FIG. 1C, once the silicon substrate 110 is kept at the temperature T1 in the vacuum chamber Cb, a monocrystalline germanium film 120 is formed on the silicon substrate 110 by employing an electron cyclotron resonance chemical vapor deposition (hereinafter referred to as ECR-CVD) approach. Here, a degree of vacuum in the vacuum chamber Cb during this process is maintained at 10⁻⁶ Ton or lower. The step of forming the monocrystalline germanium film 120 on the silicon substrate 110 by employing the ECR-CVD approach includes introducing dissociating reaction gases Rg1, Rg2 in the vacuum chamber Cb in utilization of a microwave source Mw that is electrically connected to the vacuum chamber Cb, such that the monocrystalline germanium film 120 is deposited on the silicon substrate 110.

In addition, the reaction gas Rg1 contains, for example, germane (GeH₄) and Argon (Ar) gas. Here, Argon gas will contribute to the stability of growth of the monocrystalline germanium film 120 during the epitaxial growth processes. Moreover, in the case of the existence of the Argon gas, the gas concentration ratio of hydrogen gas and germane will be in a wider range, and it will thus become more possible to adjust and achieve the desired gas concentration ratio according to various conditions of the manufacturing processes. In the existence of the Argon gas, the gas concentration ratio of the hydrogen gas (H₂) and germane (GeH₄) in the reaction gas falls in a range between 1 and 140.

It is notable that helium (He) gas and germane (GeH₄) gas are often filled in a merchant or commercial steel cylinder, wherein the helium gas is adopted for diluting the germane gas in the steel cylinder. Nevertheless, the helium gas has no contribution to epitaxial growth of monocrystalline germanium film. It is not essential for the reaction gas Rg1 as introduced in the vacuum chamber Cb to contain the helium gas.

It is worth mentioning that, throughout the epitaxial growth of monocrystalline germanium film according to the embodiment, it can be carried out at a process temperature lower than 300° C., and any annealing process is even not required. Thus, not only the thermal stress defects resulted from the discrepancy in the thermal expansion coefficients of the silicon and germanium materials can be avoided as the manufacturing processes of Ge on Si are carried out at a lower temperature according to the embodiment, but also the various restrictions on the components arisen in the conventional high-temperature process can be relieved. Consequently, it is advantageous for one to integrate the existing silicon-based semiconductor manufacturing processes with the Ge on Si low-temperature manufacturing processes according to the embodiment.

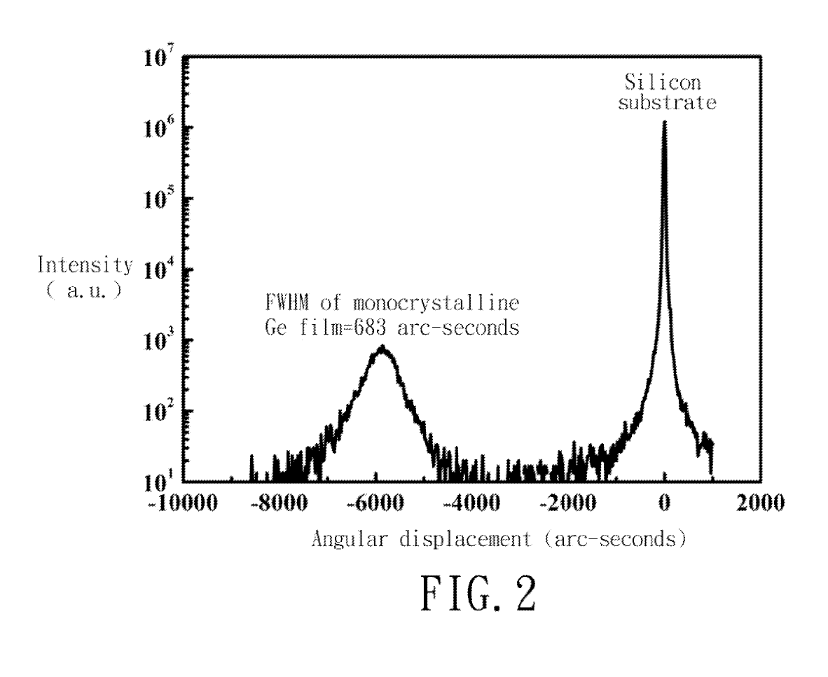

FIG. 2 is an X-ray diffraction spectrum of a monocrystalline germanium film as prepared by manufacturing processes according to one embodiment, depicting crystallographic quality results as measured by an X-ray diffractometer. The X-ray diffraction spectrum as shown in FIG. 2 is obtained by measuring the monocrystalline germanium film 120 as epitaxially grown on the silicon substrate 110, by employing the X-ray diffractometer (hereinafter referred to as XRD). It shall be appreciated that FIG. 2 depicts the full width at half maximum (hereinafter referred to as FWHM) of the monocrystalline germanium film 120 as 683 arc-seconds. In general, the FWHM of a monocrystalline germanium film as prepared by conventional processes usually falls in a range of 400-2000 arc-seconds, but a relatively excellent crystallographic quality is denoted by a value of FWHM that is lower than 1000 arc-seconds. That is to say, the FWHM of 683 arc-seconds as possessed by the monocrystalline germanium film as prepared by the processes of the invention indeed denotes a relatively excellent crystallographic quality.

It is worth mentioning that, since the ECR-CVD approach will has the merit of low ions-bombardment effects, and the epitaxially grown monocrystalline germanium film 120 as prepared by the ECR-CVD growth of the invention thus has a surface roughness that is smaller than 3 nm. Further, according to one embodiment, it is possible for one to prepare the epitaxially grown monocrystalline germanium film with a surface roughness as low as about 0.2 nm via the ECR-CVD approach according to the embodiment. Consequently, in comparison with a surface roughness (about 3 nm) of the germanium film as prepared by conventional processes, the monocrystalline germanium film as prepared by the ECR-CVD approach according to the embodiment is characterized by a relatively flattened surface with a lower surface roughness. The monocrystalline germanium film with a flattened surface of the embodiment of present invention diminishes the interfacial defect issues therein and is advantageous to the subsequent manufacturing processes and the improvement in device yield rate.

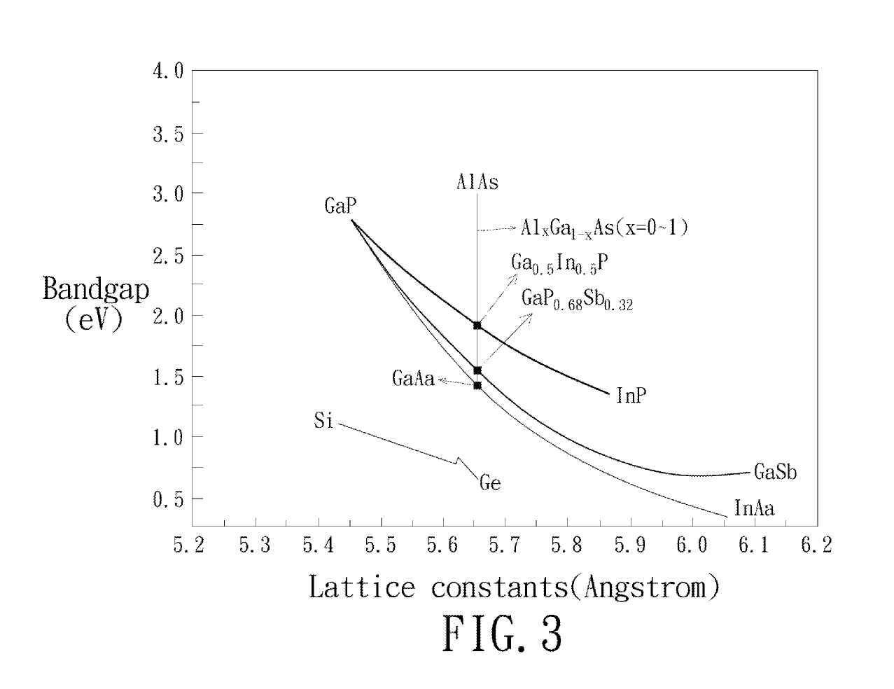

FIG. 3 is a graph depicting lattice constants vs. bandgaps of monocrystalline germanium and III-V materials. Here, as can be seen from FIG. 3, it is possible to form a device composed of a III-V compound material on the monocrystalline germanium film of the invention, depending on the necessity of such a process. In particular, it is possible to form a III-V material with a similar lattice constant as that of germanium on the monocrystalline germanium film. As shown in FIG. 3, the III-V material with a similar lattice constant as that of germanium (about 5.65) are, for example, gallium arsenide (GaAs), gallium phosphide antimonide (GaP_{0.68}Sb_{0.32}), gallium indium phosphide (Ga_{0.5}In_{0.5}P), aluminum gallium arsenide (AlₓGa₁₋ₓAs, x=0-1) and so on.

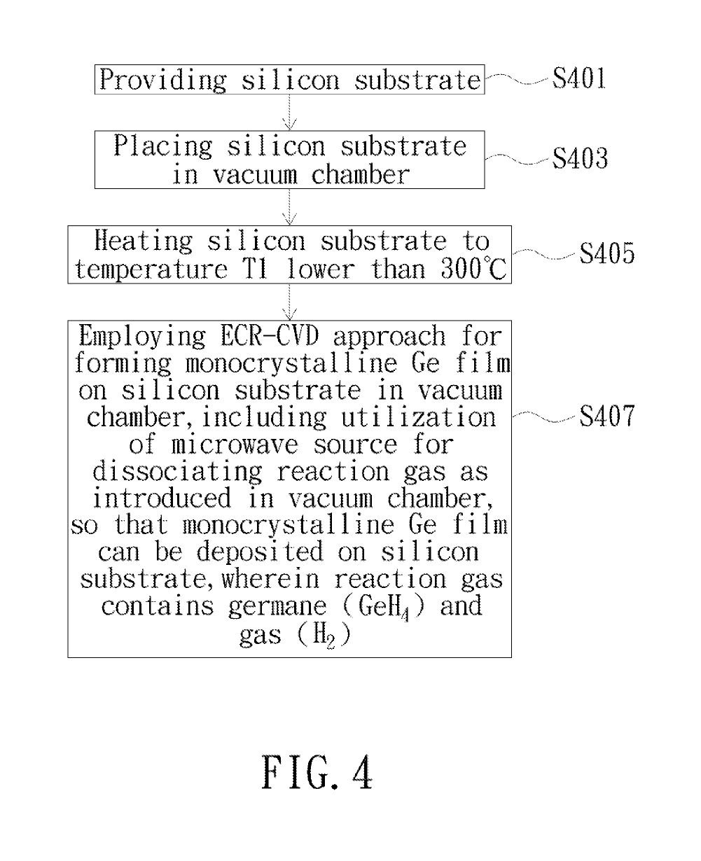

FIG. 4 is a sequential process flow chart depicting a method of epitaxial growth of a germanium film on a silicon substrate according to one embodiment of the invention. For a better understanding of the descriptions below, please refer to FIG. 4 together with FIGS. 1A-1C. In the illustrated embodiment, first of all, the silicon substrate 110 is provided (in step S401). It further involves, prior to performing the subsequent manufacturing processes, a step of eliminating a pre-existing oxidation layer 112 on the silicon substrate 110 by employing a hydrofluoric acid solution. Then, the silicon substrate 110 is placed in the vacuum chamber Cb (step S403). Next, the silicon substrate 110 is heated to a temperature T1, wherein the temperature T1 is lower than 300° C. (step S405). Besides, when heating the silicon substrate 110 with a heating plate Ht, the vacuum chamber Cb is also evacuated at the same time. Next, in the vacuum chamber Cb, the ECR-CVD approach is employed for forming the monocrystalline germanium film 120 on the silicon substrate 110, that comprises utilizing a microwave source for dissociating the reaction gas Rg1, Rg2 as introduced in the vacuum chamber Cb, so as to allow the monocrystalline germanium film 120 to be deposited on the silicon substrate 110, wherein the reaction gas Rg1 contains germane and the reaction gas Rg2 contains hydrogen gas (step S407). Moreover, the reaction gas Rg1 further contains, for example, Argon gas. Due to the presence of Argon gas, the gas concentration ratio of hydrogen gas and germane in the reaction gas falls in a broader range, such as about 1 to 140. Without the presence of Argon gas, the gas concentration ratio of hydrogen gas and germane in the reaction gas falls in a range between 1 and 10. Moreover, the monocrystalline germanium film according to the embodiment has a surface roughness lower than 3 nm. In one preferred embodiment, the monocrystalline germanium film has a surface roughness as low as about 0.2 nm. In view of detailed descriptions are set forth in the afore-mentioned paragraphs of this specification, they are thus omitted here.

In summary, according to the embodiment, the ECR-CVD approach is employed for effectively dissociating the reaction gas at a manufacturing process temperature lower than 300° C., so as to allow the monocrystalline germanium film being epitaxially grown on the silicon substrate, and prepare the monocrystalline germanium film with a surface roughness lower than 3 nm. In addition, throughout the preparation of monocrystalline germanium film according to the embodiment, it can be carried out at a process temperature lower than 300° C. Accordingly, not only the thermal stress defects resulted from the discrepancy in the thermal expansion coefficients of the silicon and germanium materials are avoided so as to improve the device yield rate, but also the various restrictions on the components arisen in conventional high-temperature process can be relieved. Consequently, it is advantageous for one to integrate the existing silicon-based semiconductor manufacturing processes with the low-temperature Ge on Si manufacturing processes of the embodiment.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method of epitaxial growth of a germanium film on a silicon substrate, comprising:
providing a silicon substrate;
placing the silicon substrate in a vacuum chamber;
heating the silicon substrate to a temperature that is lower than 300° C; and
forming a monocrystalline germanium film on the silicon substrate in the vacuum chamber, by employing an electron cyclotron resonance chemical vapor deposition approach, wherein the step of forming a monocrystalline germanium film on the silicon substrate in the vacuum chamber includes:
dissociating a reaction gas introduced into the vacuum chamber in utilization of a microwave source, such that the monocrystalline germanium film is deposited on the silicon substrate, wherein the reaction gas includes at least germane (GeH₄) and hydrogen gas (H₂).

2. The method of epitaxial growth of a germanium film on a silicon substrate according to claim 1, wherein a ratio of concentrations of hydrogen gas (H₂) and germane (GeH₄) in the reaction gas falls in a range between 1 to 10.

3. The method of epitaxial growth of a germanium film on a silicon substrate according to claim 1, wherein the reaction gas further includes Argon (Ar) gas.

4. The method of epitaxial growth of a germanium film on a silicon substrate according to claim 3, wherein a ratio of concentrations of hydrogen gas (H₂) and germane (GeH₄) in the reaction gas falls in a range between 1 and 140.

5. The method of epitaxial growth of a germanium film on a silicon substrate according to claim 1, wherein the temperature falls in a range between 150° C. and 200° C.

6. The method of epitaxial growth of a germanium film on a silicon substrate according to claim 1, wherein the monocrystalline germanium film has a surface roughness smaller than 3 nm.

7. The method of epitaxial growth of a germanium film on a silicon substrate according to claim 1, further includes:
employing a hydrofluoric acid solution, prior to placing the silicon substrate in the vacuum chamber, for eliminating a pre-existing oxidation layer on the silicon substrate.
